(19) United States
(12) Patent Application Publication
(10) Pub. No.: US 2004/0108130 A1
(43) Pub. Date: Jun. 10, 2004

(54) Mounting structure for electronic component

(75) Inventors: Masataka Suzuki, Shizuoka-ken (JP); Takayuki Arafuka, Shizuoka-ken (JP); Hiroe Suzuki, Shizuoka-ken (JP); Tomoyuki Iwata, Shizuoka-ken (JP)

Correspondence Address: Finnegan, Henderson, Farabow,, Garrett & Dunner, L.L.P., 1300 I Street, N.W., Washington, DC, 20005-3315, US

(73) Assignee: YAZAKI CORPORATION

(21) Appl. No.: 10/727,617

(22) Filed: Dec. 5, 2003

(30) Foreign Application Priority Data
Dec. 9, 2002 (JP) P2002-356800

(51) Int. Cl. H05K 1/18

(52) U.S. Cl. 174/252; 174/262; 174/260

(57) ABSTRACT

An electronic component mount structure includes a printed circuit board, a wiring portion, a through-holed portion, a heat conducting apertured portion and an electronic component. The printed circuit board has a component mount surface and a solder-dip surface. The wiring portion is formed on at least one of the component mount surface and the solder-dip surface. The through-holed portion extends through the circuit board and is connected to be electrically conductive with the wiring portion. The heat conducting apertured portion extends through the circuit board and is connected to be electrically conductive with the wiring portion. Here, the heat conducting apertured portion is formed in the vicinity of the through-holed portion. A lead portion of the electronic component is inserted to the through-holed portion of the printed circuit board from the component mount surface and soldered to the printed circuit board.

### CROSS REFERENCE TO RELATED APPLICATION

This application claims benefit of priority under 35 U.S.C. § 119 to Japanese Patent Application No. 2002-356800, filed on Dec. 9, 2002, the entire contents of which are incorporated by reference herein.

### BACKGROUND OF THE INVENTION

1. Field of the Invention

The present invention relates to mounting structures for electronic components and, more particularly, to a structure of a printed circuit board for permitting an electronic component to be connected to be electrically conductive with the printed circuit board.

2. Description of the Related Art

A mounting structure, such as one that is disclosed in FIG. 1, is known in which under a condition where lead portions of an electronic component are inserted to through-holed portions of a printed circuit board, the electronic component is connected to be electrically conductive with the printed circuit board using soldering. In this mounting structure, the printed circuit board 1 has an upper surface serving as a component mount surface 1a, and a lower surface serving as solder-dip surface 1b. Formed in a plurality of given positions of the printed circuit board 1 are through-holed portions 2, made of electrically conductive material, that extend through the printed circuit board 1. Connected to upper ends of the through-holed portions 2 are wiring portions 3 formed on the component mount surface 1a. In addition to the wiring portions 3, the electronic component 9 of the surface-mount type is also connected to the component mount surface 1a of the printed circuit board 1 by soldering. Formed around peripheries of lower ends of the through-holed portions 2 are land portions 4 that extend away from the through-holed portions 2. The land portions 4 are connectable to the wiring portions 5 formed on the solder-dip surface 1b.

In order to conductively connect the electronic component 6 to the printed circuit board 1, there are two methods which will be described below. After the lead portions 6a of the electronic component 6 are inserted to the through-holed portions 2 from the component mount surface 1a of the printed circuit board 1, the solder-dip surface 1b of the printed circuit board 1 is dipped in a flow-type soldering equipment or an immersed type soldering vessel to allow solder 7 to be adhered to the solder-dip surface 1b. Then, the solders 7 enter the through-holed portions 2, and heat transferred to the solder-dip surface 1b to be conducted to the component mount surface 1a through the through-holed portions 2. Thereafter, the solder 7 raises upward between the through-holed portion 2 and the lead portion 6a to be formed in a fillet shape, whereupon due to the solder 7 being cooled and solidified, the solder 7 forms a soldered fillet as shown in FIG. 2. This allows the electronic component 6 to be connected to be electrically conductive with the printed circuit board 1.

During soldering set forth above, when using lead-free solder (an alloy containing one to three kinds of Ag, Cu and Bi added to base metal of Sn) as the solder, in usual practice, a melting point of the lead-free solder becomes higher than a melting point of Sn/Pb eutectic solder (at 183 d° C.). For instance, the melting point of Sn/Ag3.5, the melting point of Sn/Ag3.5/Cu, the melting point of Sn/Ag3.0/Cu0.5 and the melting point of Sn/Ag3.0/Cu0.7/Bi3.0 lie at values of 221° C., 217° C., 218° C. and 211° C., respectively. However, in view of a heat-resistant conditions of the printed circuit board 1 and the electronic component 6, a soldering temperature can not be raised to a value beyond 260° C. In the presence of a slight difference between the melting point of the lead-free solder and the soldering temperature, if the temperature of the printed circuit board 1 is lowered from the soldering temperature, the temperature of the solder 7 penetrating the through-holed portions 2 rapidly reaches the freezing point of the solder 7. Therefore, the solder 7 reached to upper areas of the through-holed portions 2 has a deteriorated wetting property and spreading property and, as shown in FIG. 3, no favorable solder fillets are formed on the upper areas of the through-holed portions 2. This causes defective solder to occur between the printed circuit board 1 and the electronic component 6.

When using Sn/Pb eutectic solder as the solder 7, a difference between the melting point of Sn/Pb eutectic solder and the soldering temperature reaches an appropriate level, favorable fillets are formed as shown in FIG. 2. However, even when using Sn/Pb eutectic solder, in the presence of a slight difference between the melting point of Sn/Pb eutectic solder and the soldering temperature, there occurs the same defect as the lead-free solder.

Further, in case of using the Sn/Pb eutectic solder as the solder 7, if the solder joint portion undergoes thermal fatigue stress, the solder 7 encounters cracks as shown in FIG. 4. When using the lead-free solder as the solder 7, in general, the lead-free solder has a strength higher than that of the Sn/Pb eutectic solder, the solder 7 is hard to undergo cracks. However, since the solder 7 has no mechanism to release thermal fatigue stress such as cracks, the thermal fatigue stress acts on the printed circuit board 1. Due to such action, as shown in FIG. 5, a joint portion between the solder 7 and a wiring portion 3, a joint portion between the through-holed portion 2 and the wiring portion 3 and a joint portion between the through-holed portion 2 and the printed circuit board 1 undergo fillet-lifting b, corner-crack c and peeling d, respectively. Upon the occurrence of the fillet-lifting b, the corner-crack c and the peeling d in the vicinity of the through-holed portion 2, defect occurs in electrical conductance between the lead portions 6a of the electronic component 6 and the wiring portions 3 of the printed circuit board 1, and defect occurs in circuit connection between the wiring portions 3 on the component mount surface 1a and the wiring portions 5 on the solder-dip surface 1b.

Particularly, in case of soldering the electronic component 6 with large sized leads onto the printed circuit board 1, since large thermal fatigue stress occurs, a reliability of the solder joint portion is deteriorated and it becomes hard to use the lead-free solder. Even in case of using the Sn/Pb eutectic solder, when the thermal fatigue stress remains large, a phenomenon similar to the lead-free solder occurs to cause deterioration in electrical conductance between the lead portions 6a of the electronic component 6 and the wiring portion 3 of the printed circuit board 1, resulting in defect caused in circuit connection between the wiring portion 3 on the component mount surface 1a and the wiring portion 5 on the solder-dip surface 1b.

### SUMMARY OF THE INVENTION

It is, therefore, a first object of the present invention to provide an electronic component mount structure wherein even in the presence of a slight difference between a melting point of a solder and a soldering temperature when attempting to conductively connect an electronic component to a printed circuit board, soldering defect can be eliminated. It is a second object of the present invention to provide an electronic component mount structure wherein even in the occurrence of fillet-lifting, corner-crack or peeling in the vicinity of a through-holed portion caused by thermal fatigue stress when conductively connecting an electronic component to a printed circuit board, electrical conduction between lead portions of an electronic component and wiring portions of the printed circuit board is enhanced and circuit connection between the wiring portions formed on both surface of the printed circuit board can be enhanced.

To achieve the above object, the present invention provides a mounting structure for an electronic component, which comprises a wiring circuit board having one face serving as a component mount surface and the other face serving as a solder-dip surface, a wiring portion formed on at least one of the component mount surface and the solder-dip surface of the wiring circuit board, a through-holed portion extending through the wiring circuit board and connected to be electrically conductive with the wiring portion, a heat conducting apertured portion extending through the wiring circuit board and connected to be electrically conductive with the wiring portion, the heat conducting apertured portion being formed in the vicinity of the through-holed portion, and a lead portion of the electronic component inserted to the through-holed portion from the component mount surface and soldered to the wiring circuit board.

According to the present invention, with the lead portion of the electronic component being inserted to the through-holed portions at the component mount surface of the wiring circuit board, the wiring circuit board is placed on a flow-type soldering equipment or a dipping type soldering vessel to allow melted solder to enter the through-holed portion. Then, the heat delivered to the solder-dip surface of the wiring circuit board is conducted to the component mount surface thereof by means of the solder inside the through-holed portion, and the through-holed portion. Additionally, the heat delivered to the solder-dip surface of the wiring circuit board is conducted to the component mount surface thereof via the heat conducting apertured portion. Therefore, the end portion of the through-holed portion on the component mount surface restrict a rapid drop in temperature of the solder that has reached the upper area of the through-holed portion, resulting in an improvement in a wetting property and a spreading property of the solder. This allows the solders remaining at an upper end portion of the through-holed portion to be formed in a favorable fillet shape. As a result, a defective solder, that would occur between the wiring circuit board and the electronic component, can be minimized with no alteration made in structure of the through-holed portion and structure of the wiring portion.

### BRIEF DESCRIPTION OF THE DRAWINGS

FIG. 1 is a cross sectional view of a printed circuit board of the related art wherein an electronic component is soldered thereto.

FIG. 2 is an enlarged cross sectional view of an essential part of the printed circuit board illustrating a favorably soldered state.

FIG. 3 is an enlarged cross sectional view of an essential part of the printed circuit board illustrating an unfavorably soldered state.

FIG. 4 is an enlarged cross sectional view of an essential part of the printed circuit board illustrating a situation where cracks occur in a soldered joint portion.

FIG. 5 is an enlarged cross sectional view of an essential part of the printed circuit board illustrating a situation where fillet-lifting, corner-crack, and peeling occurred in a soldered joint portion.

FIG. 6 is a cross sectional view of a printed circuit board, with an electronic component being soldered thereto, showing a first embodiment of the present invention.

FIG. 7 is an enlarged plan view of an essential part of the printed circuit board showing the first embodiment of the present invention.

FIG. 8 is a cross sectional view of a printed circuit board, with an electronic component being soldered thereto, showing a second embodiment of the present invention.

FIG. 9A is a schematic plan view showing Example 1 of the present invention.

FIG. 9B is a schematic plan view showing Example 2 of the present invention.

FIG. 9C is a schematic plan view showing Example 3 of the present invention.

FIG. 10 is a graphic representation of the relationship between a position of a heat conducting apertured portion and a solder spread in Example 1.

FIG. 11 is a graphic representation of the relationship between a position of a heat conducting apertured portion and a solder spread in Example 2.

FIG. 12 is a graphic representation of the relationship between a position of a heat conducting apertured portion and a solder spread in Example 3.

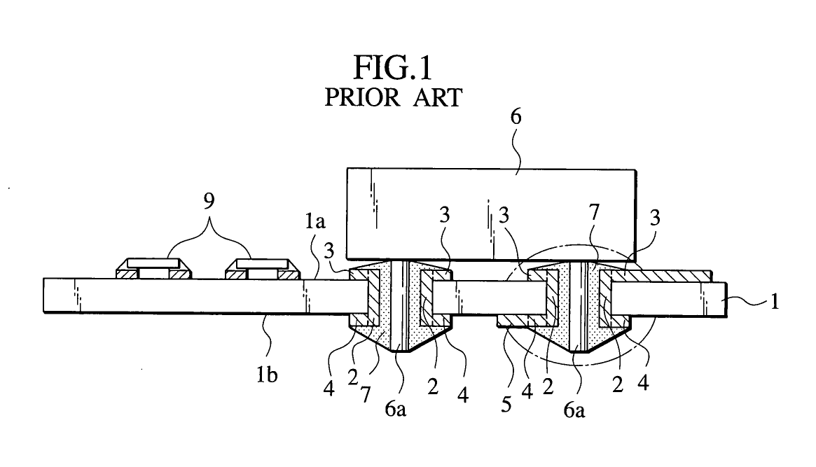

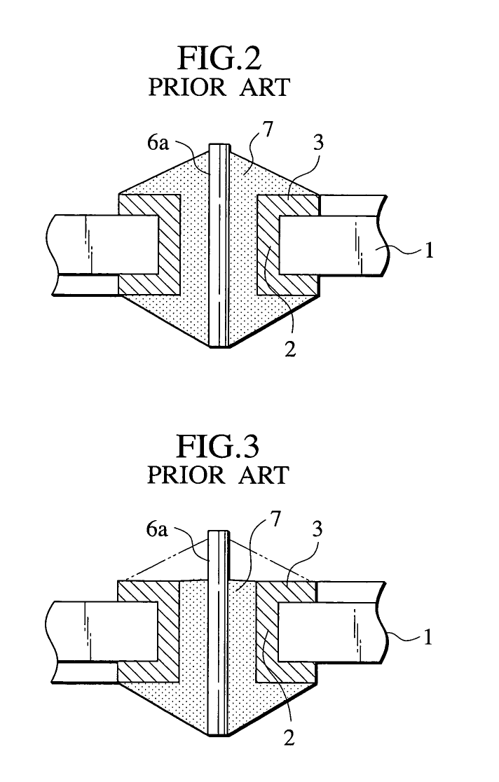

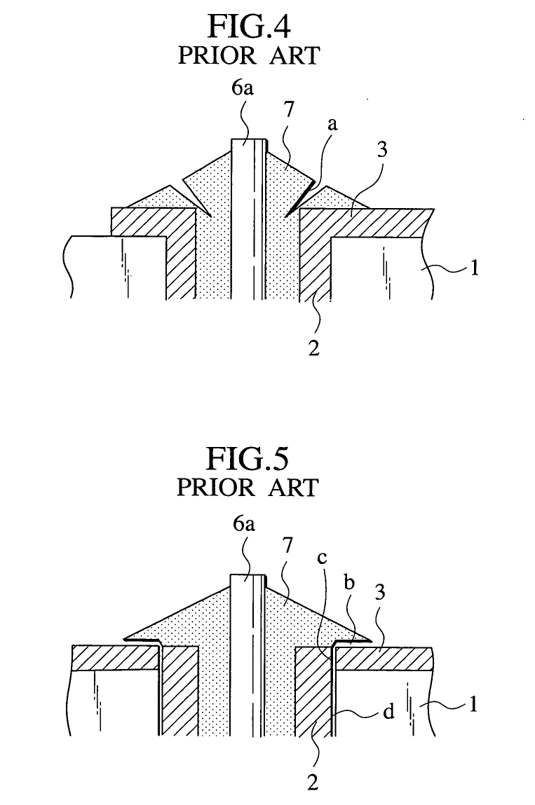

### DETAILED DESCRIPTION OF THE PREFERRED EMBODIMENTS

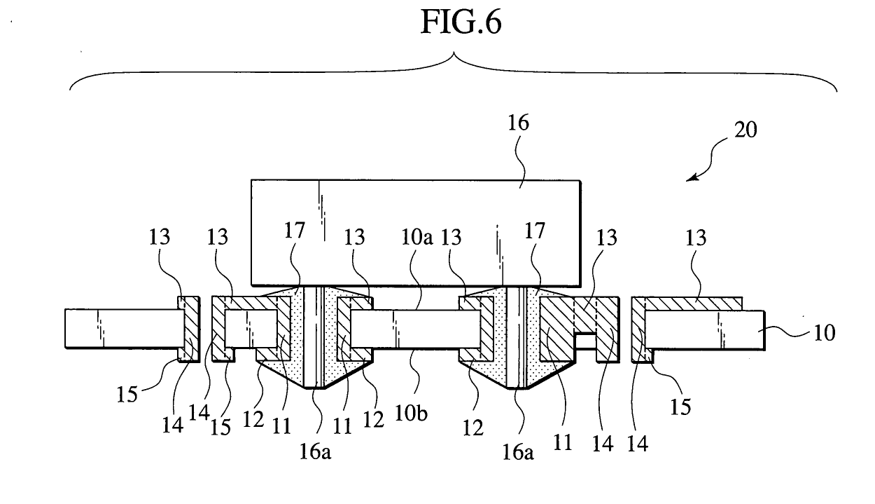

Hereunder, electronic component mount structures of first and second embodiments according to the present invention are described in conjunction with first to third Examples with reference to FIGS. 6 to 12 of the accompanying drawings, respectively.

(First Embodiment)

As shown in FIG. 6, a mounting structure 20 is comprised of a printed circuit board 10, through-holed portions 11, land portions 12, wiring portions 13, heat conducting apertured portions 14, heat collector portions 15, an electronic component 16 and solders 17.

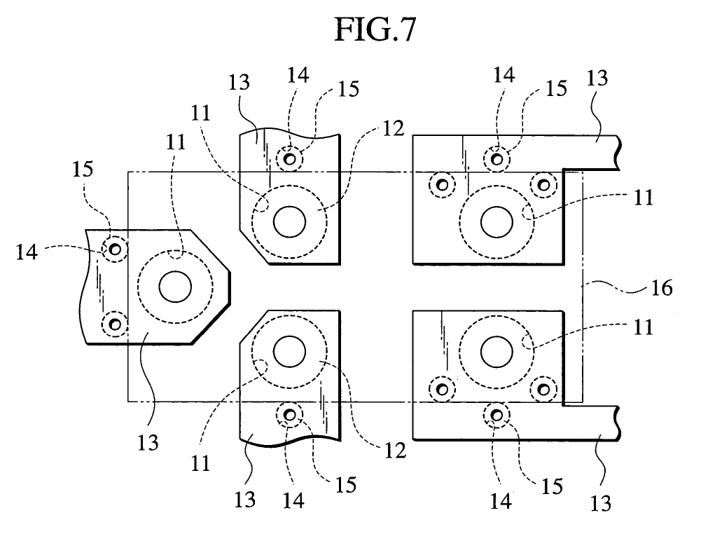

The printed circuit board 10 has an upper face serving as a component mount surface 10a and a lower face serving as a solder-dip surface 10b. The through-holed portions 11 extend through the printed circuit board 10 and each has both ends that slightly protrude away from the component mount surface 10a and the solder-dip surface 10b, respectively. The through-holed portions 11 are formed at a plurality of given locations as shown in FIG. 7. The land portions 12 are formed on the solder-dip surface 10b. The wiring portions (wiring patterns) 13 are made of copper and are formed on the component mount surface 10a. The wiring portions 13 are connected to be electrically conductive with terminal portions of the through-holed portions 11 formed on the component mount surface 10a.

The heat conducting apertured portions 14 have shapes similar to those of the through-holed portions 11 and, more particularly, extend through the printed circuit board 10 while having both ends that slightly protrude away from the component mount surface 10a and the solder-dip surface 10b, respectively. The heat conducting apertured portions 14 are formed in the vicinity of the respective through-holed portions 11 as shown in FIG. 7. The end portions, formed on the component mount surface 10a, of the heat conducting apertured portions 14 are connected to be electrically conductive with the wiring portions 13, respectively. Connected to be electrically conductive with end peripheries, formed on the solder-dip surface 10b, of the heat conducting apertured portions 14 are the heat collector portions 15 that have a high heat conductivity. Also, the heat conducting apertured portions 14 and the heat collector portions 15 are formed of the same metal as those of the through-holed portions 11 and the wiring portions 13. The heat conducting apertured portion 14 normally have a diameter of approximately 0.5 mm and, hence, even if the wiring portions 13 are formed in narrow widths, the heat conducting apertured portions 14 are connected to be electrically conductive with the wiring portions 13.

The electronic component 16 has a lower portion from which lead portions 16a extend. When soldering the electronic component 16 onto the printed circuit board 10, the lead portions 16a are inserted to the through-holed portions 11 at the component mount surface 10a of the printed circuit board 10.

The solder 17 is melted in a flow-type soldering equipment or a dip-type soldering vessel and supplied to the printed circuit board 10. When inserting the lead portions 16a into the through-holed portions 11 to allow the solder-dip surface 10b of the printed circuit board 10 to be brought into contact with the solder 17 that remain melted, the solder 17 enter into spaces between inner wall surfaces of the through-holed portions 11 and the lead portions 16a and raise toward the component mount surface 10a of the printed circuit board 10.

When the solders 17 raise through the through-holed portions 11, the heat transferred to the solder-dip surface 10b is conducted to the component mount surface 10a of the through-holed portions 11 via the solders 17 and the through-holed portions 11. In addition, the heat transferred to the solder-dip surface 10b is conducted to the component mount surface 10a of the through-holed portions 11 via the heat conducting apertured portions 14 and the wiring portions 13.

The mounting structure 20 has features listed below.

Since the heat transferred to the solder-dip surface 10b is rapidly conducted to the component mount surface 10a of the through-holed portions 11 via the through-holed portions 11, the wiring portions 13, the heat conducting apertured portions 14 and the solders 17, the component mount surface 10a of the through-holed portions 11 can reliably reach a given soldering temperature in a short time period. Also, when the temperature of the printed circuit board 10 becomes lower than the soldering temperature, the temperatures of the solders 17 are gradually lowered and reach a freezing point in areas in the vicinity of the component mount surface 10a of the through-holed portions 11 as compared to a situation where the heat conducting apertured portions 14 are not present in the printed circuit board 10. Therefore, the solders 17 reached to upper areas of the through-holed portions 11 have improved wetting properties and spreading properties to form favorable fillet shapes. As a result, even if a slight difference exists between the melting points of the solders 17 and the soldering temperature (for instance, like in a case where lead-free solder is used to form the solders 17), a defective soldering that would occur between the printed circuit board 10 and the electronic component 16 can be eliminated. Further, since the solders 17 are formed in the fillet shapes and solder contents at the soldered portions increase, a connection strength between the printed circuit board 10 and the electronic component 16 increases, resulting in an improved reliability.

Due to provision of the heat collector portions 15, having the high heat conductivity, formed on distal ends of the heat conducting apertured portions 14 on the solder-dip surface 10b, the heat transferred to the solder-dip surface 10b is efficiently conducted to the peripheral areas of the through-holed portions 11 on the component mount surface 10a via the heat conducting apertured portions 14 and the wiring portions 13.

Since all of the through-holed portions 11, the wiring portions 13, the heat conducting apertured portions 14 and the heat collector portions 15 are made of the same material, these can be fabricated in the same manufacturing process.

Also, in case of mounting the electronic component 16 with a large heat capacity onto the printed circuit board or in case of using the wiring portions 13 formed in large widths, since a heat value, required for the temperatures of the solders 17 remaining on the component mount surface 10a to be reliably raised to the soldering temperature, increases, the number of heat conducting apertured portions 14 may be preferably increased if the circumstance demands.

(Second Embodiment)

In the presently filed embodiment, the same component parts as those of the first embodiment bear like reference numerals.

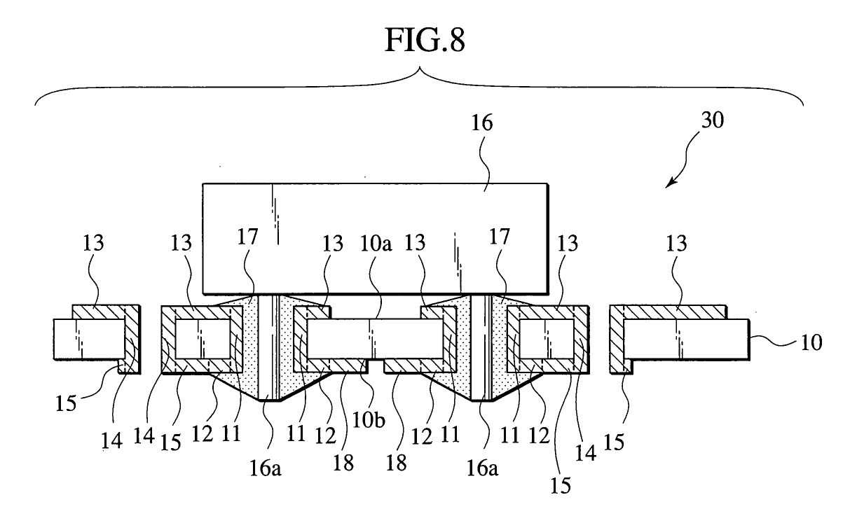

As shown in FIG. 8, a mounting structure 30 includes, in addition to the structure of the mounting structure 20, wiring portions 18 formed on the solder-dip surface 10b of the printed circuit board 10.

In the solder-dip surface 10b of the printed circuit board 10, one end of the wiring portion 18 is indirectly connected to the end of the through-holed portion 11 on the solder-dip surface 10b via the land portion 12. The heat collector portions 15, between the through-holed portions 11 and the heat conducting apertured portions 14, are connected to be electrically conductive with the land portions 12 on the solder-dip surface 10b of the printed circuit board 10, respectively. Further, on the component mount surface 10a of the printed circuit board 10, the wiring portions 13 are directly connected to the through-holed portions 11 and/or the heat conducting apertured portions 14.

The mounting structure 20 further has, in addition to the features of the mounting structure 10, other features stated below.

Even if fillet lifting caused on joint portions between the solders 17 and the wiring portions 13, corner crack caused on joint portions between the through-holed portions 11 and the wiring portions 13 and pealing caused on joint portions between the through-holed portions 11 and the printed circuit board 10 occur in the through-holed apertures 11, respectively, as a result of thermal fatigue stress, the lead portions 16a of the electronic component 16 are enabled to be connected to be electrically conductive with the wiring portions 18 on the solder-dip surface 10b in a reliable manner via the land portions 12, respectively.

Further, since circuit connections between the wiring portions 13 and the wiring portions 18 are realized through the through-holed portions 11 and the heat conducting apertured portions 14, even if defective connections occur between the through-holed portions 11 and the wiring portions 13 as a result of thermal fatigue stress, the above-described circuit connections can be reliably enhanced by means of the heat conducting apertured portions 14.

When soldering the electronic component with large sized leads onto the printed circuit board 10, large thermal fatigue stress occurs in the related art mounting structure, resulting in deterioration in a reliability of a soldered joint portion with a difficulty caused in the use of the lead-free solder. However, with the mounting structure 30, even in the occurrence of fillet-lifting, corner crack and peeling resulting from thermal fatigue stress, electrical conductance between the lead portions 16a and the wiring portions 18 and the circuit connections between the wiring portions 13 and the wiring portions 18 are reliably maintained. For this reason, it becomes possible for the electronic component part with the large sized leads to be soldered to the printed circuit board 10 using lead-free solder.

Also, the number of heat conducting apertured portions 14 are determined so as to satisfy conditions described below. The heat conducting apertured portions 14 may be set in a given number of pieces such that even in the occurrence of defective connections between the through-holed portions 11 and the wiring portions 13 as a result of thermal fatigue stress, the use of the heat conducting apertured portions 14 are able to allow electric current to flow between the wiring portions 18 and the wiring portions 13 at a desired flow rate per unit time. Further, although in normal practice, the heat conducting apertured portions 14 are formed in a diameter of approximately 0.5 mm, the heat conducting apertured portions 14 may be formed in a further increased diameter.

### EXAMPLE 1

Test was conducted to investigate the relationship between a distance between the through-holed portion 11 and the heat conducting apertured portion 14, under a condition where the heat conducting apertured portion 14 was formed on the printed circuit board 10 at a single location in the vicinity of the through-holed portion 11, and the degree (in a length: mm) of the solder spread that was present in a lateral direction of the solder as a result of the solder exuding from the end of the through-holed portion 11 on the component mount surface 10a.

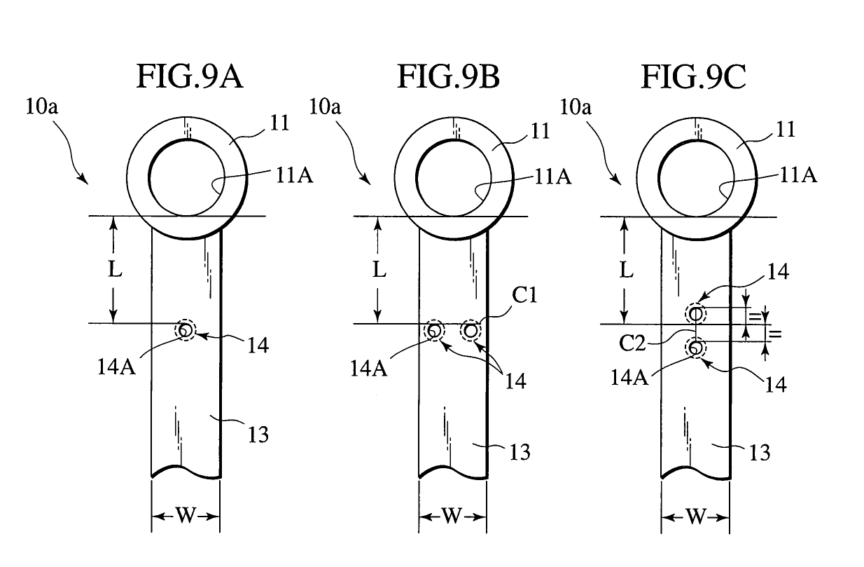

As shown in FIG. 9A, the printed circuit board 10 formed with the through-holed portion 11 and the heat conducting apertured portion 14 was prepared. The heat conducting apertured portion 14 was formed at a center in a widthwise direction of the wiring portion 13 extending away from the end of the through-holed portion 11 on the component mount surface 10a.

The wiring portion 13 had a width W of 1.0 mm. The shortest distance L between an inner wall surface 11A of the through-holed portion 11 and an inner wall surface 14A of the heat conducting apertured portion 14 was chosen to lie in a range between 0.4 mm and 4.0 mm. The solder-dip surface 10b of the printed circuit board 10 was dipped in the solder, and measurement was conducted on the degree of the solder spread that was present in a lateral direction of the solder as a result of the solder exuding from the end of the through-holed portion 11 on the component mount surface 10a.

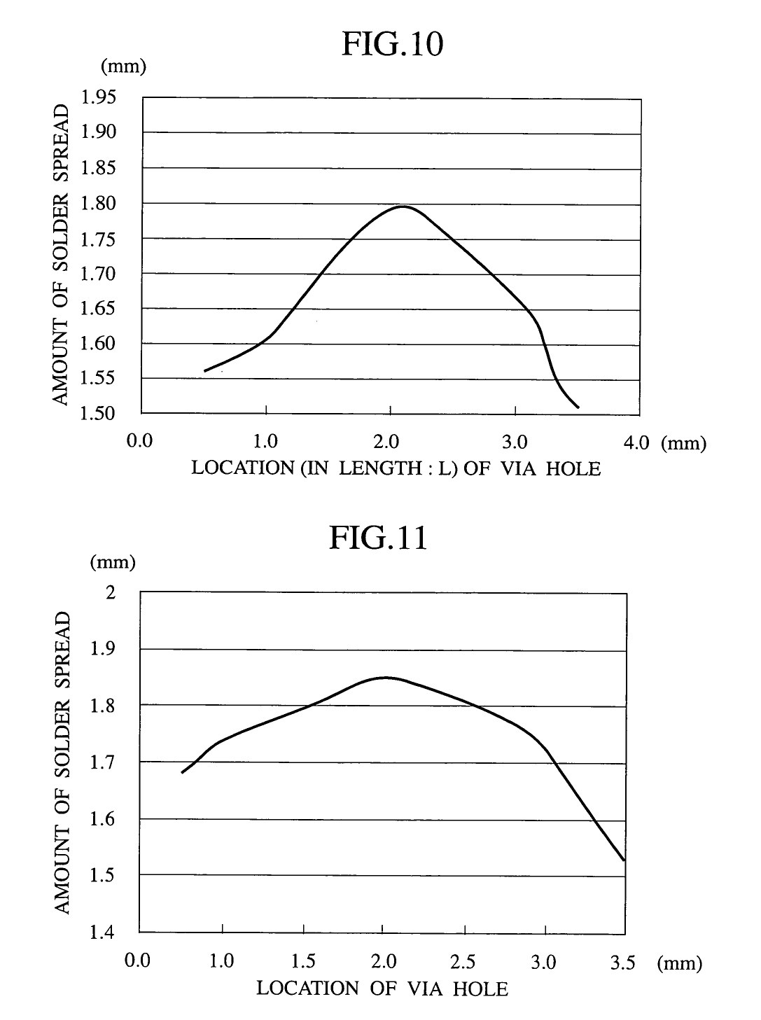

As a result, as shown in FIG. 10, under a range in which the shortest distance L reached a value equal to or greater than 0.5 mm and equal to or less than 3.4 mm, the solder spread reached a value greater than 1.55 mm, resulting in formation of favorable solder fillet. Also, even in the presence of an increase in the width of the wiring portion 13 to a value of 2 mm, a similar result was obtained.

### SECOND EXAMPLE

Test was conducted to investigate the relationship between a distance between the through-holed portion 11 and the heat conducting apertured portions 14, under a condition where the heat conducting apertured portions 14 were formed on the printed circuit board 10 in a lateral direction of the wiring portion 13 at two locations in the vicinity of the through-holed portion 11, and the degree (in a length: mm) of the solder spread that was present in the lateral direction of the solder as a result of the solder exuding from the end of the through-holed portion 11 on the component mount surface 10a.

As shown in FIG. 9B, the printed circuit board 10 formed with the through-holed portion 11 and the two heat conducting apertured portions 14 located in a lateral direction was prepared. The wiring portion 13 had a width W of 2.0 mm. The shortest distance L between the inner wall surface 11A of the through-holed portion 11 and a line segment C1 interconnecting inner wall surfaces 14A of the heat conducting apertured portions 14 at positions closest to the through-holed portion 11 was chosen to lie in a range between 0.5 mm and 3.5 mm. The solder-dip surface 10b of the printed circuit board 10 was dipped in the solder, and measurement was conducted on the degree of the solder spread that was present in a lateral direction of the solder as a result of the solder exuding from the end of the through-holed portion 11 on the component mount surface 10a.

As a result, as shown in FIG. 11, under a range in which the shortest distance L reached a value equal to or greater than 0.5 mm and equal to or less than 3.4 mm, the solder spread reached a value greater than 1.55 mm, resulting in formation of favorable solder fillet.

### THIRD EXAMPLE

Test was conducted to investigate the relationship between a distance between the through-holed portion 11 and the heat conducting apertured portions 14, under a condition where the heat conducting apertured portions 14 were formed on the printed circuit board 10 in a longitudinal direction of the wiring portion 13 at two locations in the vicinity of the through-holed portion 11, and the degree (in a length: mm) of the solder spread that was present in the lateral direction of the solder as a result of the solder exuding from the end of the through-holed portion 11 on the component mount surface 10a.

As shown in FIG. 9C, the printed circuit board 10 formed with the through-holed portion 11 and the two heat conducting apertured portions 14 located in the longitudinal direction was prepared. The wiring portion 13 had a width W of 1.5 mm. The shortest distance L between the inner wall surface 11A of the through-holed portion 11 and a center of a line segment C2 interconnecting the inner wall surfaces 14A, at areas closest to the through-holed portion 11, of the heat conducting apertured portions 14 was chosen to lie in a range between 0.5 mm and 3.0 mm. The solder dip surface 10b of the printed circuit board 10 was dipped in the solder, and measurement was conducted on the degree of the solder spread that was present in the lateral direction of the solder as a result of the solder exuding from the end of the through-holed portion 11 on the component mount surface 10a.

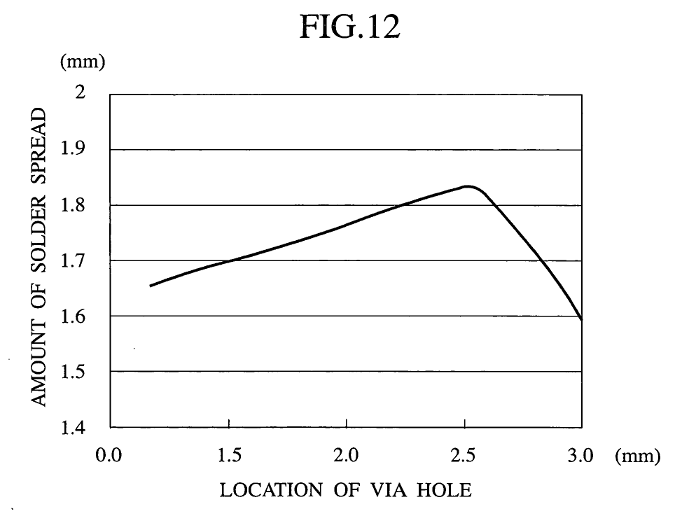

As a result, as shown in FIG. 12, under a range in which the shortest distance L reached a value equal to or greater than 0.5 mm and equal to or less than 3.0 mm, the solder spread reached a value greater than 1.55 mm, resulting in formation of favorable solder fillet.

From the foregoing Examples 1 to 3 set forth above, it appears that if the distance between the heat conducting apertured portion 14 and the through-holed portion 11 lies in a value equal to or greater 0.5 mm and equal to or less than 3.0 mm, the solder spread reached to a value greater than 1.55 mm and solder fillet was formed on the component mount surface in a favorable shape. Also, in usual practice, it is hard, in view of a production quality of the circuit board, for the heat conducting apertured portion 14 to be placed closer to the through-holed portion 11 in a value less than 0.5 mm.

As set forth above, although the present invention has been described with reference to the first and second embodiments and the first to third Examples it is to be noted that the present invention is not limited by the specific disclosure herein and various alterations following a principal concept of the structure may be possibly made.

For instance, while in the various embodiments set forth above, the heat conducting members 14 have been shown in the form of tubular shapes similar to the through-holed portions 11, it may be possible to take a structure in which the insides of the heat conducting members 14 are filled with electrically conducting material having a high heat conductivity.

What is claimed is:

1. A mounting structure for an electronic component, comprising:
a wiring circuit board having one face serving as a component mount surface and the other face serving as a solder-dip surface;
a wiring portion formed on at least one of the component mount surface and the solder-dip surface of the wiring circuit board;
a through-holed portion extending through the wiring circuit board and connected to be electrically conductive with the wiring portion;
a heat conducting apertured portion extending through the wiring circuit board and connected to be electrically conductive with the wiring portion, the heat conducting apertured portion being formed in the vicinity of the through-holed portion; and
a lead portion of the electronic component inserted to the through-holed portion from the component mount surface and soldered to the wiring circuit board.

2. The mounting structure according to claim 1, further comprising:
a heat collector portion extending from an end of the heat conducting apertured portion on the solder-drip surface, the heat collector portion being made of metal.

3. The mounting structure according to claim 2, wherein the heat collector portion is connected to be electrically conductive with an end of the through-holed portion on the solder-dip surface.

4. The mounting structure according to claim 1, wherein the heat conducting apertured portion is formed in a via hole.

5. The mounting structure according to claim 4, wherein the via hole is located at a center of the wiring portion in a widthwise direction thereof and the shortest distance between an inner wall of the via hole and an inner wall of the through-holed portion lies in a range equal to or greater than 0.5 mm and equal to or less than 3 mm.

6. The mounting structure according to claim 4, wherein two via holes are located in the wiring portion in a widthwise direction thereof and the shortest distance between a line segment interconnecting inner walls, at positions closest to the through-holed portion, of the via holes and an inner wall of the through-holed portion lies in a range equal to or greater than 0.5 mm and equal to or less than 3 mm.

7. The mounting structure according to claim 4, wherein two via holes are located in the wiring portion in a longitudinal direction thereof and the shortest distance between a center of a line segment interconnecting inner walls, at positions closest to the through-holed portion, of the via holes and an inner wall of the through-holed portion lies in a range equal to or greater than 0.5 mm and equal to or less than 3 mm.
